(19) United States
(12) Patent Application Publication
(10) Pub. No.: US 2021/0218081 A1
(43) Pub. Date: Jul. 15, 2021

(54) Method of Recycling Lead-Acid Battery Waste into Lead Halide for Resource Utilization and Purification

(71) Applicant: South China University of Technology, Guangzhou (CN)

(72) Inventors: Keyou Yan, Guangzhou City (CN); Zidan Liu, Guangzhou City (CN)

(73) Assignee: South China University of Technology, Guangzhou (CN)

(21) Appl. No.: 17/134,596

(22) Filed: Dec. 28, 2020

(30) Foreign Application Priority Data
Dec. 28, 2019 (CN) 201911383995.3

(51) Int. Cl. H01M 10/54; H01M 10/12

(52) U.S. Cl. CPC H01M 10/54; H01M 10/12

(57) ABSTRACT

The present disclosure discloses a method of recycling lead-acid battery waste into lead halide for resource utilization and purification. The method includes: subjecting a lead paste material from spent lead-acid batteries to halogenation and purification with a chemical wet process to obtain a halide, which can be used to prepare a novel photovoltaic light-emitting device. This method realizes the purpose of recycling and value-added utilization of wastes. The present disclosure provides a method for purifying a halide from a lead paste material of spent lead batteries, which has a simple process, strong operability, low energy consumption, and no production of toxic waste gas and liquid, thus achieving the purpose of energy conservation and emission reduction. Moreover, the halide is used to prepare a novel photovoltaic light-emitting device, which achieves the value-added utilization and changes the traditional lead paste recycling concept.

### TECHNICAL FIELD

The present disclosure belongs to the field of environmental protection, and specifically relates to a method of recycling spent lead-acid battery into lead halide for resource utilization and purification.

### BACKGROUND

Spent lead-acid batteries include a large amount of sulfuric acid and lead compounds with different valences, and if these substances are not treated properly, it will result in a hazardous waste of lead resources and environmental pollution. With rapid development in the lead-acid battery industry, China has become the largest producer of recycled lead in the world. China has an output of recycled lead increasing year by year, whose proportion in total lead usage has not changed much, slightly less than one-third of the total lead usage. China faces the following problems in the production of recycled lead: small proportion of recycled lead in lead production, low utilization rate, lack of a formal recycling network, and overall backwardness of industrial technology and equipment.

Reasonable recycling of spent lead-acid batteries is still an arduous and urgent problem to be solved. At present, the treatment of spent lead-acid batteries generally includes the pyrometallurgy (fire) method, the hydrometallurgy (wet) method and their-combination related method. Because a fire treatment process often requires the use of carbonaceous reducing agents, and inevitably produces lead-containing fumes and waste gases such as sulfur dioxide and carbon dioxide, which will cause heavy environmental pollution, serious harms to the health of operators, and so on. Therefore, the fire method will eventually be eliminated to some extent. With the increasing requirements for environmental protection, the wet recycling of spent lead-acid batteries has shown obvious advantages in this regard. However, due to problems such as large amount of waste water treatment, high energy consumption, expensive materials such as polar plates, and complex production systems, the existing wet treatment methods also have bleak prospects in their development. Therefore, people are forced to seek for new treatment methods.

In recent years, organic-inorganic halide perovskite materials have become a research hotspot in the field of optoelectronics due to their advantages such as high absorption coefficient, long carrier lifetime, adjustable band gap, and low cost. Solar cells and light-emitting diodes prepared from the materials have led to great achievements and gradually show promising application prospects. According to statistics of the National Renewable Energy Laboratory (NREL), a perovskite solar cell can achieve a maximum certified energy conversion efficiency of 25.2%. As an electroluminescent material, a perovskite light-emitting diode can achieve an external quantum efficiency higher than 20% according to the latest report on “Nature”. A precursor solution for making a perovskite material includes the main components of PbI₂, PbBr₂, and PbCl₂. As described in the U.S. Pat. No. 9,590,278 B2 and documents thereof (Chen, Po-Yen, et al. “Environmentally responsible fabrication of efficient perovskite solar cells from recycled car batteries.” Energy & Environmental Science 7.11 (2014): 3659-3665), lead iodide was successfully purified from waste batteries, but toxic gases were produced during the treatment process, and heating at a high temperature was required, thus resulting in high energy consumption. Therefore, there is a need for an energy-saving and emission-reducing method that is environmentally-friendly and easy to operate.

### SUMMARY

In order to overcome the above-mentioned shortcomings in the prior art, the present disclosure provides a method of recycling lead-acid battery waste into lead halide for resource utilization and purification, which adopts a chemical wet method to avoid high-temperature energy consumption.

The present disclosure is intended to solve the problems of complex production process, high energy consumption, high cost, low recovery rate and limited application scope in recycling lead from a lead paste material of spent lead-acid batteries. The technical problem to be solved by the present disclosure is to provide a wet halogenation and purification method for a lead paste with low energy consumption from the perspective of environmental protection, which can be directly used in the field of novel photovoltaic and light-emitting devices to achieve the purpose of value-added utilization. The present disclosure provides a new idea for lead paste recycling.

The objective of the present disclosure is achieved by at least one of the following technical solutions.

The present disclosure provides a method of recycling lead-acid battery waste into lead halide for resource utilization and purification, including the following steps:

(1) mixing sulfuric acid with water in a reaction tank, and stirring a resulting solution thoroughly to obtain a sulfuric acid solution;

(2) adding a lead paste to the sulfuric acid solution obtained in step (1) and mixing thoroughly to obtain a mixed solution;

(3) adding a hydrogen peroxide solution to the mixed solution obtained in step (2) and thoroughly stirring; reacting at room temperature to completely convert lead dioxide in the system into lead oxide and then convert lead oxide into lead sulfate under acidic conditions to obtain a slurry; filtering the slurry (preferably pumping the slurry into a filter press for filtration) to obtain a filtrate and a filter cake; and recovering and reusing the filtrate with sulfuric acid;

(4) mixing solid sodium hydroxide and water thoroughly to obtain a sodium hydroxide solution; adding the filter cake obtained in step (3) to the sodium hydroxide solution, and stirring and reacting to obtain a stirred mixture; adjusting pH of the stirred mixture to 10.0 to 11.0, and conducting a first conversion reaction; pumping a reaction solution into a filter press for filtration to obtain a filtrate and a first-conversion filter cake; and subjecting the filtrate to evaporation and crystallization to obtain a by-product of sodium sulfate;

(5) thoroughly mixing the first-conversion filter cake obtained in step (4) with an acid solution, and conducting a second conversion reaction; pumping a reaction solution into a filter press for filtration to obtain a filtrate and a second-conversion filter cake; recovering and reusing the filtrate with acidity; and drying the second-conversion filter cake to obtain lead halide.

Further, the sulfuric acid solution in step (1) may have a concentration of 10 g/L to 300 g/L.

Further, the lead paste and the sulfuric acid solution in step (2) may have a weight ratio of 1:(1-30).

Further, the sulfuric acid solution in step (1) and the hydrogen peroxide solution in step (3) may have a volume ratio of (4-200):1; and the hydrogen peroxide solution in step (3) may have a mass percentage concentration of 30%.

Further, the reaction at room temperature in step (3) may be conducted for 1 h to 5 h.

Further, the sodium hydroxide solution in step (4) may have a concentration of 0.5 mol/L to 1 mol/L.

Further, the filter cake and the sodium hydroxide solution in step (4) may have a mass-volume ratio of 80 to 170 (g/L); and the stirring and reacting may be conducted for 1 h to 5 h.

Preferably, in step (4), pH of the stirred mixture may be adjusted to 10.0.

Further, the first conversion reaction in step (4) may be conducted for 1 h to 5 h.

Further, the acid solution in step (5) may be a hydroiodic acid, hydrobromic acid or hydrochloric acid solution; and the acid solution may have a mass percentage concentration of 20% to 60%.

Preferably, the acid solution in step (5) may be hydroiodic acid; and the hydroiodic acid may have a concentration of 57 wt %.

When hydroiodic acid is adopted as the acid solution in step (5), a lead halide obtained is lead iodide, and a recovered filtrate includes hydroiodic acid.

When hydrobromic acid is adopted as the acid solution in step (5), a lead halide obtained is lead bromide, and a recovered filtrate includes hydrobromic acid.

When hydrochloric acid is adopted as the acid solution in step (5), a lead halide obtained is lead chloride, and a recovered filtrate includes hydrochloric acid.

Further, the acid solution in step (5) and the lead paste in step (2) may have a mass ratio of (2-5):1; and the second conversion reaction may be conducted for 1 h to 5 h.

The lead halide obtained in step (5) can be used in the preparation of photovoltaic and light-emitting devices, such as the preparation of perovskite solar cells and perovskite LEDs.

In the halogenation and purification method for a lead paste from spent lead-acid batteries provided in the present disclosure, preferably, the hydrogen peroxide solution may be added in a manner where the hydrogen peroxide solution flows evenly along all tank side walls of the reaction tank to the middle bottom of the reaction tank via draft tubes.

In the halogenation and purification method for a lead paste from spent lead-acid batteries provided in the present disclosure, in the step (5), hydrobromic acid or hydrochloric acid can also be added to the reaction tank as a reactant to prepare lead bromide or lead chloride.

Compared with the prior art, the present disclosure has the following advantages and beneficial effects.

(1) In the method of recycling lead-acid battery waste into lead halide for resource utilization and purification according to the present disclosure, treated raw materials mainly include a lead paste material from spent lead-acid batteries, namely, a mixture material with lead sulfate, lead dioxide, lead monoxide and lead, which results in low cost and environmental friendliness.

(2) In the method of recycling lead-acid battery waste into lead halide for resource utilization and purification according to the present disclosure, all reactions are conducted at room temperature without requiring heating, which leads to low energy consumption and avoids the issues of high recovery difficulty and low recovery rate in traditional methods for recycling lead. The present disclosure provides a new idea for treating a lead paste from lead-acid batteries. Moreover, the present disclosure is simple in production process, low in cost, and easy to be used for large-scale production.

(3) In the method of recycling lead-acid battery waste into lead halide for resource utilization and purification according to the present disclosure, the filtrate obtained in step (4) is subjected to evaporation and crystallization to obtain sodium sulfate, and the sodium sulfate can be collected and sold, thus realizing the reasonable treatment of a waste liquid; the filtrates obtained in steps (3) and (5) can be reused to realize the recycling of waste liquids; and there is no waste water and waste residue generated during the whole process, which fundamentally achieves substantial reduction in emissions and thus avoids the problems of large amounts of waste water treatment, heavy environmental pollution, and the like in the prior art. The method of the present disclosure is a clean and environmentally-friendly recycling method that can achieve high recovery of lead halide, which also provides a new idea for treating a lead paste from lead batteries.

(4) The method of recycling lead-acid battery waste into lead halide for resource utilization and purification according to the present disclosure uses no toxic reagents and thus produces no toxic gases such as chlorine, sulfur dioxide, and nitric oxide, thereby resulting in low toxicity and low equipment corrosion.

### BRIEF DESCRIPTION OF DRAWINGS

FIG. 1 is a structural diagram for the perovskite solar cells prepared in Example 1 and Example 3;

FIG. 2 is a structural diagram for the LED device prepared in Example 2;

FIG. 3 is a process flow diagram of the method of recycling lead-acid battery waste into lead halide for resource utilization and purification according to an example of the present disclosure.

### DETAILED DESCRIPTION

The specific implementation of the present disclosure will be further described below in conjunction with examples, but the implementation and protection of the present disclosure are not limited thereto. It should be noted that the processes that are not specifically described in detail below can be implemented or understood by those skilled in the art with reference to the prior art. All of the used reagents or instruments which are not specified with manufacturers are conventional commercially-available products.

### EXAMPLE 1

This example provided a method for conducting halogenation and purification on lead-acid battery waste and utilizing an obtained product in a novel photovoltaic light-emitting device.

As shown in FIG. 3, a halogenation and purification method for lead-acid battery waste included the following steps:

### 1.1 Reductive Conversion of a Lead Paste of Spent Lead-Acid Batteries

Main chemical reaction equations:

PbO₂+H₂O₂=PbO+H₂O+O_{2↑} (acidic conditions);

PbO₂+H₂SO₄=PbSO₄+H₂O;

Pb+PbO₂+2H₂SO₄=2PbSO₄+2H₂O.

14 L of a sulfuric acid solution with a mass concentration of 30 g/L was prepared in a 20 L reaction tank as a reaction solution, and mechanical stirring was started to thoroughly mix the sulfuric acid solution. 100 mL of a hydrogen peroxide solution with a mass percentage concentration of 30% was prepared, and metering pumps and related pipelines were accurately connected to the reaction tank to ensure that the hydrogen peroxide solution would be added evenly. Then 1,000 g of a dry lead paste was added, and reaction was conducted for 1 h at room temperature; after the reaction was completed, an obtained slurry was pumped into a filter press for filtration to obtain a filtrate and a filter cake; and the filtrate was discharged into the reaction tank for recycling. The filter cake included lead sulfate with an amount of 1,000 g to 1,200 g.

### 1.2 Main Chemical Reaction Equation

PbSO∝2+2NaOH=Pb(OH)₂+Na₂SO₄.

12 L of a 0.5 mol/L sodium hydroxide solution was added to another reaction tank; then the filter cake (lead sulfate) obtained in the last step was added, and a resulting mixture reacted for 1 h under stirring; and pH of the system in the reaction tank was finely adjusted to 10.0, and conversion reaction was conducted for 1 h. After the reaction was completed, an obtained slurry was pumped into a filter press for filtration to obtain a filtrate and a first-conversion filter cake. The obtained filtrate was subjected to evaporation and crystallization, and a product of sodium sulfate was collected, which could be sold. The first-conversion filter cake included lead hydroxide with an amount of 800 g to 1,000 g.

### 1.3 Main Chemical Reaction Equation

Pb(OH)₂+2HX=PbX_{2↓}+2H₂O

The first-conversion filter cake obtained was added to a new reaction tank, 2 kg of hydroiodic acid with a mass percentage content of 57 wt % (taking hydroiodic acid as an example) was added to the tank, and conversion reaction was conducted for 1 h. After the reaction was completed, an obtained slurry was pumped into a filter press for filtration to obtain a filtrate and a second-conversion filter cake; the obtained filtrate with hydroiodic acid was subjected to evaporation, and an obtained product was collected for reuse; and the second-conversion filter cake was dried to obtain lead iodide. The second-conversion filter cake included 400 g to 800 g of lead iodide.

The above lead iodide was dissolved in DMF, and a waste residue was discarded; then a resulting DMF solution was subjected to recovery evaporation or directly heated on a heating plate; and an obtained dry solid (purified lead iodide) was used for preparing a perovskite material in the next step.

### 1.4 Preparation of a Perovskite Solar Cell

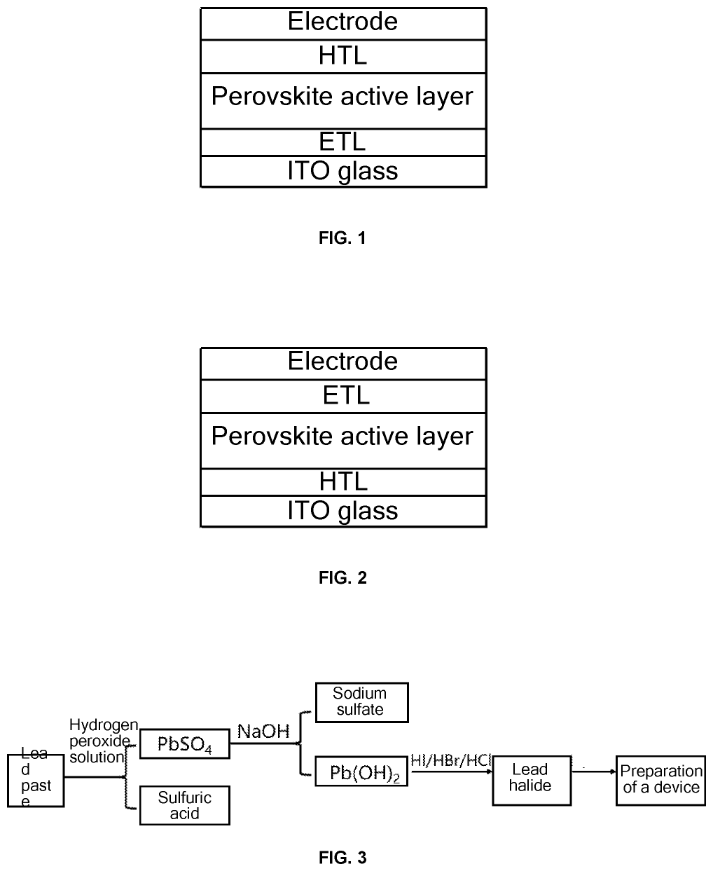

The solar cell was prepared step by step from bottom to top according to the schematic diagram in FIG. 1.

(1) Cleaning of an Indium Tin Oxide (ITO) Glass:

an ITO glass with a sheet resistance of 10Ω, a light transmittance of 90%, and a thickness of 1.1 mm was selected and subjected to ultrasonic cleaning for 5 min successively in deionized water, detergent, acetone, and absolute ethanol, then blow-dried with nitrogen, and treated for 20 min with an ultraviolet (UV)-ozone cleaner.

(2) Preparation of an Electron Transport Layer (ETL)

23 mg of SnCl₂.2H₂O was dissolved in 1 mL of absolute ethanol, and an obtained solution after complete dissolution was spin-coated on the ITO substrate for 30 s at a rotational speed of 3,000 rpm. Finally, a spin-coated thin film was heated for 1 h on a heating plate at 230° C., then cooled, and treated for 5 min in UV-ozone to form the ETL.

(3) Preparation of a Perovskite Thin Film:

the purified lead iodide (PbI₂), CH₃NH₃I and DMSO were dissolved in DMF at a molar ratio of 1:1:1 to obtain a perovskite precursor solution with a concentration of 1.3 mol/mL. After the substances were completely dissolved, the perovskite precursor solution was dropped on SnO₂ by spin-coating at 1,000 rpm for 10 s, then the rotational speed was increased to 5,000 rpm, and 160 μl of chlorobenzene was dropped at the 10th s. A spin-coated perovskite thin film was heated on a 65° C. heating plate for 1 min and then on a 100° C. heating plate for 10 min.

(4) Preparation of a Hole Transport Layer (HTL):

72 mg of spiro-OMeTAD, 28 μl of TBP, and 17.5 μl of lithium salt (520 mg dissolved in 1 mL of acetonitrile) were mixed, and finally a resulting spiro-OMeTAD mixed solution was dropped on the surface of the perovskite thin film by spin-coating at 3,000 rpm for 35 s.

(5) Preparation of a Metal Electrode:

Under the vacuum condition of 1.0×10⁻³ Pa, gold was vapor-deposited on the spiro-OMeTAD thin film to prepare a metal electrode with a thickness of 100 nm, and thus the perovskite solar cell was obtained.

### EXAMPLE 2

This example provided a method for conducting halogenation and purification on lead-acid battery waste and utilizing an obtained product in a novel photovoltaic light-emitting device.

As shown in FIG. 3, a halogenation and purification method for lead-acid battery waste included the following steps:

### 2.1 Reductive Conversion of a Lead Paste of Spent Lead-Acid Batteries

Main chemical reaction equations:

PbO₂+H₂O₂=PbO+H₂O+O_{2↑} (acidic conditions);

PbO+H₂SO₄=PbSO₄+H₂O;

Pb+PbO₂+2H₂SO₄=2PbSO₄+2H₂O.

14 L of a sulfuric acid solution with a mass concentration of 70 g/L was prepared in a 20 L reaction tank as a reaction solution, and mechanical stirring was started to thoroughly mix the sulfuric acid solution. 1,000 mL of a hydrogen peroxide solution with a mass percentage concentration of 30 wt % was prepared, and metering pumps and related pipelines were accurately connected to the reaction tank to ensure that the hydrogen peroxide solution would be added evenly. Then 1,000 g of a dry lead paste was added, and reaction was conducted for 3 h at room temperature; after the reaction was completed, an obtained slurry was pumped into a filter press for filtration to obtain a filtrate and a filter cake; and the filtrate was discharged into the reaction tank for recycling. The filter cake included lead sulfate with an amount of 1,000 g to 1,200 g.

### 2.2 Main Chemical Reaction Equation

PbSO₄+2NaOH=Pb(OH)₂+Na₂SO₄.

10 L of a 0.8 mol/L sodium hydroxide solution was added to another reaction tank; then the filter cake (lead sulfate) obtained in the last step was added, and a resulting mixture reacted for 1 h under stirring; and pH of the system in the reaction tank was finely adjusted to 10.0, and conversion reaction was conducted for 3 h. After the reaction was completed, an obtained slurry was pumped into a filter press for filtration to obtain a filtrate and a first-conversion filter cake. The obtained filtrate was subjected to evaporation and crystallization, and a product of sodium sulfate was collected, which could be sold. The first-conversion filter cake included lead hydroxide with an amount of 800 g to 1,000 g.

### 2.3 Main Chemical Reaction Equation

Pb(OH)₂+2HBr=PbBr₂↓+2H₂O

The first-conversion filter cake obtained was added to a new reaction tank, 3 kg of hydrobromic acid with a mass percentage content of 47% was added to the tank, and conversion reaction was conducted for 3 h. After the reaction was completed, an obtained slurry was pumped into a filter press for filtration to obtain a filtrate and a second-conversion filter cake; the obtained filtrate with hydrobromic acid was subjected to evaporation, and an obtained product was collected for reuse; and the second-conversion filter cake was dried to obtain lead bromide. The second-conversion filter cake included 300 g to 600 g of lead bromide.

The above lead bromide was dissolved in DMF, and a waste residue was discarded; then a resulting DMF solution was subjected to recovery evaporation or directly heated on a heating plate; and an obtained dry solid (purified lead bromide) was used for preparing a perovskite material in the next step.

### 2.4 Preparation of Perovskite LED

The LED was prepared step by step from bottom to top according to the schematic diagram in FIG. 2.

(1) Cleaning of an ITO Glass:

an ITO glass with a sheet resistance of 10Ω, a light transmittance of 90%, and a thickness of 1.1 mm was selected and subjected to ultrasonic cleaning for 5 min successively in deionized water, detergent, acetone, and absolute ethanol, then blow-dried with nitrogen, and treated for 20 min with a UV-ozone cleaner.

(2) Preparation of an HTL

PEDOT: PSS was dropped on a plasma-treated ITO by spin-coating at 4,000 rpm for 60 s; and after the spin-coating was completed, an obtained film was subjected to annealing treatment for 20 min on a 150° C. hot plate.

(3) Preparation of a Perovskite Thin Film:

50.5 mg of the PbBr2 solid powder obtained in 2.3 was weighed and mixed with 18.2 mg of MABr and 22.6 mg of CsBr, and a resulting mixture was dissolved in 1 mL of a mixture of DMF and DMSO to obtain a perovskite precursor solution. After the substances were completely dissolved, the perovskite precursor solution was spin-coated on PEDOT: PSS.

(4) Preparation of an ETL and an Electrode:

the above sample was transferred to a vacuum evaporation system, and TPBI and aluminum electrode were deposited successively, with thicknesses of 40 nm and 100 nm, respectively.

After the above steps were completed, the novel perovskite LED device was obtained.

### EXAMPLE 3

This example provided a method for conducting halogenation and purification on lead-acid battery waste and utilizing an obtained product in a novel photovoltaic light-emitting device.

As shown in FIG. 3, a halogenation and purification method for lead-acid battery waste included the following steps:

### 3.1 Reductive Conversion of a Lead Paste of Spent Lead-Acid Batteries

Main chemical reaction equations:

PbO₂+H₂O₂=PbO+H₂O+O₂↑ (acidic conditions);

315 PbO+H₂SO₄=PbSO₄+H₂O;

Pb+PbO₂+2H₂SO₄=2PbSO₄+2H₂O.

14 L of a sulfuric acid solution with a mass concentration of 30 g/L was prepared in a 20 L reaction tank as a reaction solution, and mechanical stirring was started to thoroughly mix the sulfuric acid solution. 3,500 mL of a hydrogen peroxide solution with a mass percentage concentration of 30% was prepared, and metering pumps and related pipelines were accurately connected to the reaction tank to ensure that the hydrogen peroxide solution would be added evenly. Then 1,000 g of a dry lead paste was added, and reaction was conducted for 5 h at room temperature; after the reaction was completed, an obtained slurry was pumped into a filter press for filtration to obtain a filtrate and a filter cake; and the filtrate was discharged into the reaction tank for recycling. The filter cake included lead sulfate with an amount of 1,000 g to 1,200 g.

### 3.2 Main Chemical Reaction Equation

PbSO₄+2NaOH=Pb(OH)₂+Na₂SO₄.

6 L of a 1 mol/L sodium hydroxide solution was added to another reaction tank; then the filter cake (lead sulfate) obtained in the last step was added, and a resulting mixture reacted for 1 h under stirring; and pH of the system in the reaction tank was finely adjusted to 11.0, and conversion reaction was conducted for 5 h. After the reaction was completed, an obtained slurry was pumped into a filter press for filtration to obtain a filtrate and a first-conversion filter cake. The obtained filtrate was subjected to evaporation and crystallization, and a product of sodium sulfate was collected, which could be sold. The first-conversion filter cake included lead hydroxide with an amount of 800 g to 1,000 g.

### 3.3 Main Chemical Reaction Equation

Pb(OH)₂+2HX=PbX_{2↓}+2H₂O

The first-conversion filter cake obtained was added to a new reaction tank, 5 kg of hydroiodic acid with a mass percentage content of 57 wt % (taking hydroiodic acid as an example) was added to the tank, and conversion reaction was conducted for 5 h. After the reaction was completed, an obtained slurry was pumped into a filter press for filtration to obtain a filtrate and a second-conversion filter cake; the obtained filtrate with hydroiodic acid was subjected to evaporation, and an obtained product was collected for reuse; and the second-conversion filter cake was dried to obtain lead iodide. The second-conversion filter cake included 400 g to 800 g of lead iodide.

The above lead iodide was dissolved in DMF, and a waste residue was discarded; then a resulting DMF solution was subjected to recovery evaporation or directly heated on a heating plate; and an obtained dry solid (purified lead iodide) was used for preparing a perovskite material in the next step.

### 3.4 Preparation of a Photovoltaic LED

The solar cell was prepared step by step from bottom to top according to the schematic diagram in FIG. 1.

(1) Cleaning of an ITO Glass:

an ITO glass with a sheet resistance of 10Ω, a light transmittance of 90%, and a thickness of 1.1 mm was selected and subjected to ultrasonic cleaning for 5 min successively in deionized water, detergent, acetone, and absolute ethanol, then blow-dried with nitrogen, and treated for 20 min with a UV-ozone cleaner.

(2) Preparation of an ETL

23 mg of SnCl₂.2H₂O was dissolved in 1 mL of absolute ethanol, and an obtained solution after complete dissolution was spin-coated on the ITO substrate for 30 s at a rotational speed of 3,000 rpm. Finally, a spin-coated thin film was heated for 1 h on a heating plate at 230° C., then cooled, and treated for 5 min in UV-ozone to form the ETL.

(3) Preparation of a Perovskite Thin Film:

the purified lead iodide (PbI₂), CH₃NH₃I and DMSO were dissolved in DMF at a molar ratio of 1:1:1 to obtain a perovskite precursor solution with a concentration of 1.3 mol/mL. After the substances were completely dissolved, the perovskite precursor solution was dropped on SnO₂ by spin-coating at 1,000 rpm for 10 s, then the rotational speed was increased to 5,000 rpm, and 160 μl of chlorobenzene was dropped at the 10th s. A spin-coated perovskite thin film was heated on a 65° C. heating plate for 1 min and then on a 100° C. heating plate for 10 min.

(4) Preparation of an HTL:

72 mg of spiro-OMeTAD, 28 μl of TBP, and 17.5 μl of lithium salt (520 mg dissolved in 1 mL of acetonitrile) were mixed, and finally a resulting spiro-OMeTAD mixed solution was dropped on the surface of the perovskite thin film by spin-coating at 3,000 rpm for 35 s.

(5) Preparation of a Metal Electrode:

Under the vacuum condition of 1.0×10⁻³ Pa, gold was vapor-deposited on the spiro-OMeTAD thin film to prepare a metal electrode with a thickness of 100 nm, and thus the photovoltaic LED was obtained.

The above examples are only preferred implementations of the present disclosure, which are only used to explain rather than limit the present disclosure. Any changes, substitutions, modifications, or the like made by those skilled in the art without departing from the spirit of the present disclosure shall fall within the protection scope of the present disclosure.

What is claimed is:

1. A method of recycling lead-acid battery waste into lead halide for resource utilization and purification, comprising the following steps:
(1) mixing sulfuric acid with water and stirring a resulting solution thoroughly to obtain a sulfuric acid solution;
(2) adding a lead paste to the sulfuric acid solution obtained in step (1) and mixing thoroughly to obtain a mixed solution;
(3) adding a hydrogen peroxide solution to the mixed solution obtained in step (2) and thoroughly stirring; reacting at room temperature to obtain a slurry, and filtering the slurry to obtain a filtrate and a filter cake; and recovering the filtrate with sulfuric acid;
(4) mixing sodium hydroxide and water thoroughly to obtain a sodium hydroxide solution; adding the filter cake obtained in step (3) to the sodium hydroxide solution, and stirring and reacting to obtain a stirred mixture; adjusting pH of the stirred mixture to 10 to 11, and conducting a first conversion reaction; filtering a reaction solution to obtain a filtrate and a first-conversion filter cake; and subjecting the filtrate to evaporation and crystallization to obtain a by-product of sodium sulfate; and
(5) thoroughly mixing the first-conversion filter cake obtained in step (4) with an acid solution, and conducting a second conversion reaction; filtering a reaction solution to obtain a filtrate and a second-conversion filter cake; recovering the filtrate to obtain an acid solution; and drying the second-conversion filter cake to obtain lead halide.

2. The method of recycling lead-acid battery waste into lead halide for resource utilization and purification according to claim 1, wherein, the sulfuric acid solution in step (1) has a concentration of 10 g/L to 300 g/L.

3. The method of recycling lead-acid battery waste into lead halide for resource utilization and purification according to claim 1, wherein, the lead paste and the sulfuric acid solution in step (2) have a weight ratio of 1:(1-30).

4. The method of recycling lead-acid battery waste into lead halide for resource utilization and purification according to claim 1, wherein, the sulfuric acid solution in step (2) and the hydrogen peroxide solution in step (3) have a volume ratio of (4-200):1; and the hydrogen peroxide solution in step (3) has a mass percentage concentration of 30%.

5. The method of recycling lead-acid battery waste into lead halide for resource utilization and purification according to claim 1, wherein, the reaction at room temperature in step (3) is conducted for 1 h to 5 h.

6. The method of recycling lead-acid battery waste into lead halide for resource utilization and purification according to claim 1, wherein, the sodium hydroxide solution in step (4) has a concentration of 0.5 mol/L to 1 mol/L.

7. The method of recycling lead-acid battery waste into lead halide for resource utilization and purification according to claim 1, wherein, the filter cake and the sodium hydroxide solution in step (4) have a mass-volume ratio of 80 to 170 (g/L); and the stirring and reacting is conducted for 1 h.

8. The method of recycling lead-acid battery waste into lead halide for resource utilization and purification according to claim 1, wherein, the first conversion reaction in step (4) is conducted for 1 h to 5 h.

9. The method of recycling lead-acid battery waste into lead halide for resource utilization and purification according to claim 1, wherein, the acid solution in step (5) is a hydroiodic acid, hydrobromic acid or hydrochloric acid solution; and the acid solution has a mass percentage concentration of 20% to 60%.

10. The method of recycling lead-acid battery waste into lead halide for resource utilization and purification according to claim 1, wherein, the acid solution in step (5) and the lead paste in step (2) have a mass ratio of (2-5):1; and the second conversion reaction is conducted for 1 h to 5 h.
